(19) United States
(12) Patent Application Publication
(10) Pub. No.: US 2013/0163213 A1
(43) Pub. Date: Jun. 27, 2013

(54) MOUNTING APPARATUS FOR CIRCUIT BOARD

(71) Applicants: PO-WEN CHIU, Tu-Cheng (TW); ZHAN-YANG LI, Shenzhen City (CN); WEN-HU LU, Shenzhen City (CN)

(72) Inventors: PO-WEN CHIU, Tu-Cheng (TW); ZHAN-YANG LI, Shenzhen City (CN); WEN-HU LU, Shenzhen City (CN)

(21) Appl. No.: 13/658,748

(22) Filed: Oct. 23, 2012

(30) Foreign Application Priority Data
Dec. 27, 2011 (CN) 201110444182.8

(51) Int. Cl. H05K 5/02

(52) U.S. Cl. 361/752

(57) ABSTRACT

A mounting apparatus includes a chassis and a fixing module. The chassis includes a bottom plate, and a circuit board attached to the bottom plate. The fixing module includes a blocking member. The blocking member is rotatably secured to the bottom plate and abuts the circuit board, to prevent the circuit board from moving along a direction parallel to the bottom plate.

### BACKGROUND

1. Technical Field

The present disclosure relates to mounting apparatuses, more particularly to a mounting apparatus for a circuit board.

2. Description of Related Art

Printed circuit boards (PCBs), such as a motherboard or an expansion card, must be firmly mounted in computer enclosures. Conventionally, the PCB is directly mounted to a computer chassis with rivets or screws. The computer chassis may also form protrusions for receiving the rivets or screws and supporting the PCB. When the computer enclosure is vibrated, the PCB may be easily moved relative to the enclosure.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, cutaway, isometric view of an embodiment of a mounting apparatus and a circuit board.

FIG. 2 is an enlarged view of the circled portion II of FIG. 1.

FIG. 3 is an assembled view of the mounting apparatus and the circuit board of FIG. 1, and the fixing module blocks the circuit board.

FIG. 4 is another assembled view of the mounting apparatus and the circuit board of FIG. 1, but the fixing module releases the circuit board.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

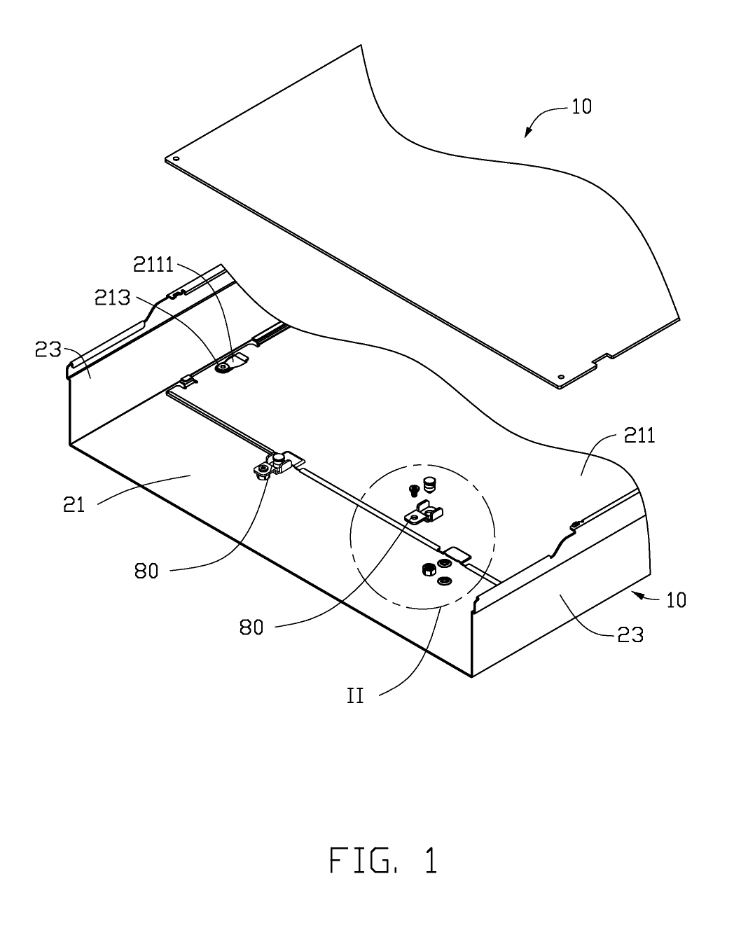

FIG. 1 illustrates an embodiment of a mounting apparatus configured to secure a circuit board 10. The mounting apparatus includes a chassis 20 and two fixing modules 80.

The chassis 20 includes a bottom plate 21, two sidewalls 23, and a rear plate (not shown) located on the bottom plate 21. The two sidewalls 23 extend from two opposite sides of the bottom plate 21. The two sidewalls 23 are substantially parallel to each other and perpendicular to the bottom plate 21. A bearing plate 211 is attached to the bottom plate 21 and can support the circuit board 10. Two protrusions 2111 are located on the bearing plate 211, corresponding to the two fixing modules 80. The bottom plate 21 defines a first securing holes 213 and a second securing hole 214, located in front of the bearing plate 211. Two limiting portions 215 are located on the bottom plate 21, corresponding to each of the two fixing modules 80. Each of the limiting portions 215 defines a limiting hole 2151. The circuit board 10 is attached to the bearing plate 211 and located between the two sidewalls 23.

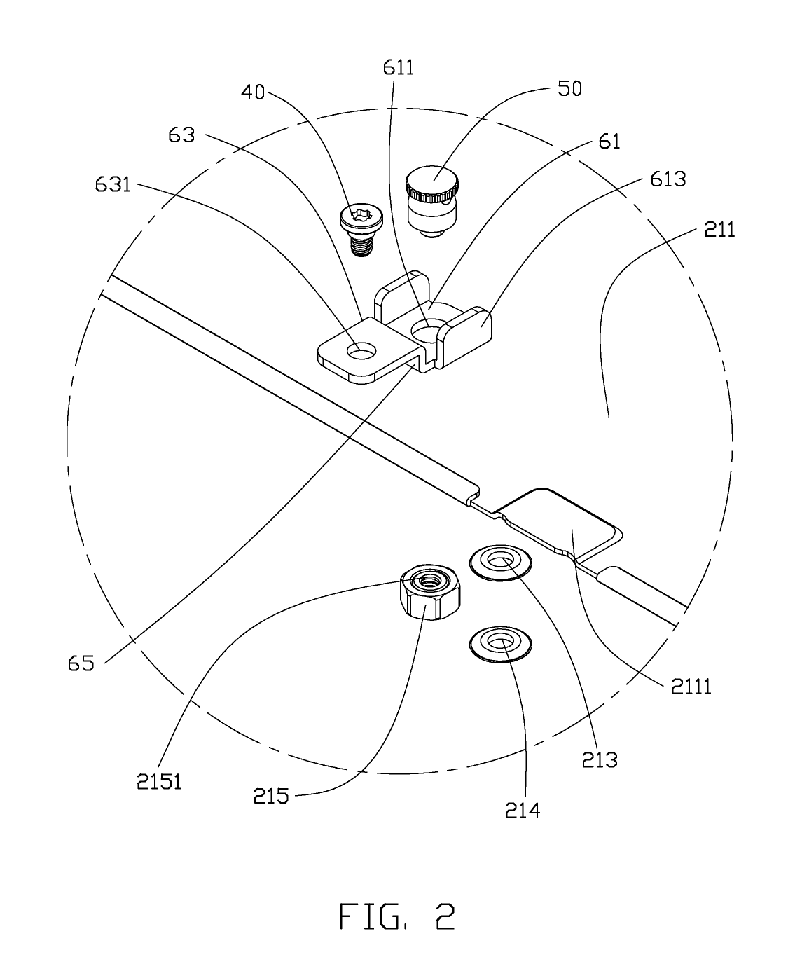

Referring to FIG. 2, each of the two fixing modules 80 includes a securing member 40, a locking member 50, and a blocking member 60.

The blocking member 60 includes a blocking board 61, a fixing board 63, and a connecting portion 65 connecting the blocking board 61 and the fixing board 63. The blocking board 61 defines a locking hole 611 corresponding to the first securing hole 213. The fixing board 63 defines a fixing hole 631 corresponding to the limiting hole 2151. The blocking board 61 has a first extending direction towards the bearing plate 211. The fixing board 63 has a second extending direction opposite to the first extending direction. The blocking board 61 is substantially parallel to the fixing board 63 and the bottom plate 21. The connecting portion 65 is substantially perpendicularly connected to the blocking board 61 and the fixing board 63. Two resisting pieces 613 are located on opposite sides of the blocking board 61. The two resisting pieces 613 are substantially parallel to each other and perpendicular to the blocking board 61.

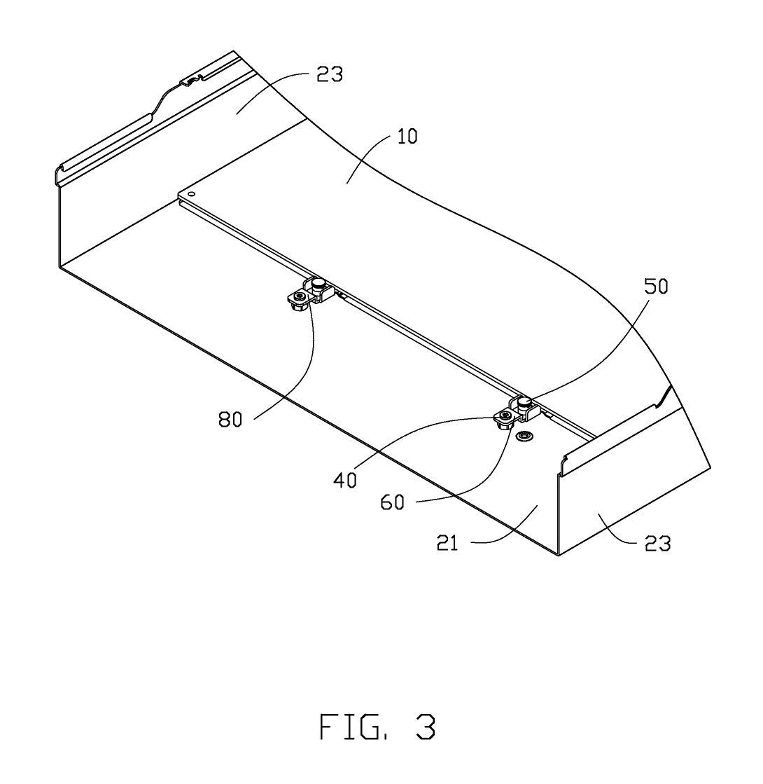

Referring to FIG. 3, describing installing one of the two fixing modules 80 to the chassis 20, the blocking member 60 of the fixing module 80 is placed in front of the circuit board 10 and adjacent to the circuit board 10. The fixing board 63 abuts the limiting portion 215 to align the fixing hole 631 with the limiting hole 2151. The securing member 40 is locked into the fixing hole 631 and the limiting hole 2151, to rotatably secure the blocking member 60 to the limiting portion 215. The blocking board 61 abuts the circuit board 10. The locking member 50 is locked into the locking hole 611 and the first securing hole 213, to position the blocking member 60. Thus when the blocking member 60 is located in a first position, it blocks the circuit board 10, to prevent the circuit board 10 from being moved along a direction parallel to the bottom plate 21.

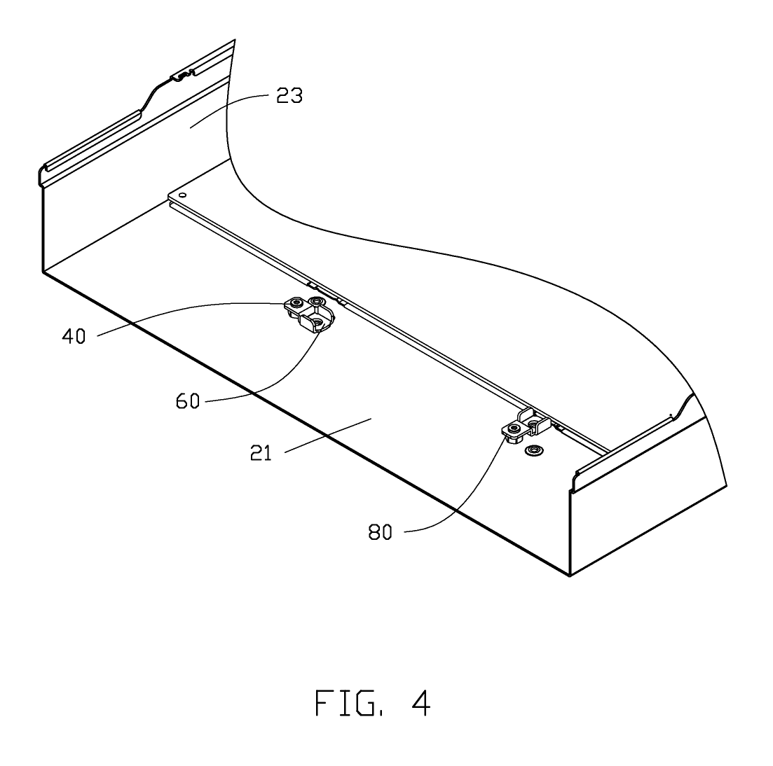

Referring to FIG. 4, to release the circuit board 10, the locking member 50 is unlocked from the first securing hole 213. The blocking member 60 is rotated around the securing member 40, until the locking hole 611 is aligned with the second securing hole 214. When the blocking member 60 is in a second position, the blocking member 60 is disengaged from the circuit board 10. The locking member 50 is locked into the locking hole 6111 and the second securing hole 214, to fix the blocking member 60.

It is to be understood, however, that even though numerous characteristics and advantages have been set forth in the foregoing description of embodiments, together with details of the modules and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A mounting apparatus comprising:
a chassis, the chassis comprises a bottom plate, a circuit board attached to the bottom plate, and a limiting portion locating the bottom plate; and
a fixing module, the fixing module comprising a blocking member, the blocking member being rotatably secured to the limiting portion and abuts the circuit board, to prevent the circuit board from moving along a direction parallel to the bottom plate.

2. The mounting apparatus of claim 1, wherein the blocking member comprises a fixing board and a blocking board, the fixing board is rotatably secured to the bottom plate, and the blocking board abuts the circuit board.

3. The mounting apparatus of claim 2, wherein the blocking member further comprises a connecting portion, connecting the fixing board and the blocking board, and the connecting portion is substantially perpendicular to the fixing board and the blocking board.

4. The mounting apparatus of claim 3, wherein the fixing board is substantially parallel to the blocking board.

5. The mounting apparatus of claim 2, wherein the fixing module further comprises a securing member; the fixing board defines a fixing hole; the limiting portion defines a limiting hole; and the securing member is engaged in the fixing hole and the limiting hole, to rotatably secure the blocking member to the limiting portion.

6. The mounting apparatus of claim 2, wherein the fixing module further comprises a locking member; the blocking board defines a locking hole; the bottom plate defines a first securing hole; and the fixing module is engaged in the locking hole and the first securing hole, to prevent the blocking member from being moved relative to the bottom plate.

7. A mounting apparatus for a circuit board, comprising:
a chassis, the chassis comprising a bottom plate, the circuit board being attached to the bottom plate; and
a fixing module, the fixing module comprising a blocking member, the blocking member being secured to the bottom plate and comprising a blocking board; the blocking member is rotatable between a first position and a second position relative to the bottom plate, when the blocking member is located in the first position, the blocking board abuts the circuit board to prevent the circuit board movable along a direction parallel to the bottom plate; when the blocking member is located in the second position, the blocking board is disengaged from the circuit board, to release the circuit board.

8. The mounting apparatus of claim 7, wherein the blocking member further comprises a fixing board, the fixing board is rotatably secured to the bottom plate.

9. The mounting apparatus of claim 8, wherein the blocking member further comprises a connecting portion, connecting the fixing board and the blocking board, and the connecting portion is substantially perpendicular to the fixing board and the blocking board.

10. The mounting apparatus of claim 8, wherein the fixing board is substantially parallel to the blocking board.

11. The mounting apparatus of claim 8, wherein the fixing module further comprises a securing member; the fixing board defines a fixing hole, a limiting portion with a limiting hole is located on the bottom plate; and the securing member is engaged in the fixing hole and the limiting hole, to rotatably secure the blocking member to the limiting portion.

12. The mounting apparatus of claim 7, wherein the fixing module further comprises a locking member; the blocking board defines a locking hole, the bottom plate defines a securing hole; and the fixing module is engaged in the locking hole and the securing hole, to prevent the blocking member movable relative to the bottom plate.
